(19) United States
(12) Patent Application Publication
(10) Pub. No.: US 2011/0148526 A1
(43) Pub. Date: Jun. 23, 2011

(54) Low noise amplifier with variable frequency response

(75) Inventors: Shey-Shi Lu, Taipei City (TW); Yu-Hsiang Wang, Kaohsiung City (TW); Kuan-Ting Lin, Taipei City (TW)

(73) Assignee: National Taiwan University, Taipei City (TW)

(21) Appl. No.: 12/803,578

(22) Filed: Jun. 30, 2010

(30) Foreign Application Priority Data
Dec. 23, 2009 (TW) 098144606

(51) Int. Cl. H03F 3/16

(52) U.S. Cl. 330/277

(57) ABSTRACT

The present invention relates a low noise amplifier with adaptive frequency responses and method of altering frequency responses thereof. The low noise amplifier comprises an inductive degeneration circuit, N cascode circuits and N switches. The inductive degeneration circuit has an input impedance and a frequency response characteristic. Each of the cascode circuits is connected in parallel to the inductive degeneration circuit. Each of the switches is connected to a corresponding cascode circuit respectively. Each of the cascode circuit is turned ON or OFF by enabling or disabling the corresponding switches to alter the frequency response characteristic.

### FIELD OF THE INVENTION

The present invention relates to an amplifier and a method for frequency response switching; in particular, the present invention relates to a low noise amplifier with variable frequency response and a method for frequency response switching.

### BACKGROUND OF THE INVENTION

Recently, wireless communication industries have been comprehensively and vigorously developed, and numerous standards and services therefore have been proposed or applied. For example, Wireless Local Area Network (WLAN) uses frequency bands of 2.4 GHz, 5.2 GHz and 5.7 GHz, Global System for Mobile (GSM) cellular phones uses frequency bands of 0.9 GHz, 1.8 GHz and 1.9 GHz. In addition, Global Positioning System (GPS) adopts the frequency band at 1.5 GHz. Based on such a need for multiple frequency bands, most of current solutions emphasize largely, by means of many standard and integrated manufacture processes using CMOS, on integrating the multi-frequency wireless transceiver amplification circuit into a wideband low noise wireless transceiver chip.

However, using the wideband low noise wireless transceiver chip to receive electromagnetic signals on all frequency bands may lead to the occurrence of interference in the amplification circuit caused by electromagnetic signals of different frequencies, thus undesirably deteriorating relevant features of amplification gain or noise figure thereof.

Refer now to FIG. 1, wherein a circuit diagram for a cascode low noise amplifier in prior art is shown. In the figure, the cascode low noise amplifier 1 comprises a primary transistor T1, a secondary transistor T2, a source inductor Ls and a gate inductor Lg, and the parasitic capacitance Cgs exists between the gate and the source of the primary transistor T1. The cascode low noise amplifier 1 demonstrates features of narrowband and low noise, and also under ideal conditions, the maximum power match and the minimum noise match can be achieved at the same time. Besides, the input impedance is determined according to the source inductor Ls, the parasitic capacitance Cgs existing between the gate and the source as well as the gate inductor Lg, which can be expressed as below:

$$Zin = s ( Lg + Ls ) + \frac{1}{SCgs} + \frac{gm 1 Ls}{Cgs}$$

where gm1 indicates the current gain of the primary transistor T1, S is a complex number.

According to the Miller effect, it can be appreciated that the gain offered by the primary transistor T1 may cause the Cgd to adversely affect the frequency response at high frequency in the cascode low noise amplifier 1. But, such a cascode structure allows the cascode low noise amplifier 1 to be able to effectively suppress the Miller effect in the primary transistor T1, thereby acquiring better frequency responses and higher gains at high frequency, and also improving the isolation and stability in the cascode low noise amplifier 1. Additionally, the frequency response characteristic of the cascode low noise amplifier 1 can be configured through the W/L value of the primary transistor T1, in which W represents the channel width parameter of T1, L the channel length parameter thereof.

### SUMMARY OF THE INVENTION

In view of the drawbacks found in prior art, the objective of the present invention is to provide a low noise amplifier with variable frequency response and a method for frequency response switching, so as to resolve the problem of deterioration in features of amplification gain or noise figure caused by interference from signals on different frequency bands when receiving electromagnetic signals on all frequency bands by using the wideband low noise amplification circuit.

According to the objective of the present invention, a low noise amplifier with variable frequency response is herein provided, comprising a source inductive degeneration amplification circuit, N cascode circuits and N switches, where N is a positive integer. The source inductive degeneration amplification circuit with an input impedance and a frequency response characteristic, the source inductive degeneration amplification circuit comprises at least one output terminal and at least one inductor with one terminal connecting to a ground. Each of the cascode circuits is connected in parallel between an output terminal of the source inductive degeneration amplification circuit and the other terminal of the inductor. Each of the switches is respectively connected to each cascode circuit so as to allow each cascode circuit to be turned ON or OFF by means of enabling or disabling each switch, thereby changing the frequency response characteristic.

Herein, the source inductive degeneration amplification circuit comprises a first transistor, a second transistor, a first inductor, a second inductor and a third inductor. The drain of the first transistor connected to the source of the second transistor, the first inductor is connected between the gate of the first transistor and an input terminal, the second inductor is connected between the source of the first transistor and a ground, one terminal of the third inductor is connected to the drain of the second transistor and an output terminal, while the other terminal of the third inductor is connected to a first voltage source.

Herein each cascode circuit respectively comprises a third transistor and a fourth transistor. And, in each cascode circuit, the source of the fourth transistor is connected to the drain of the third transistor, the drain of the fourth transistor is connected to the drain of the second transistor, and the source of the third transistor is connected to the source of the first transistor.

Herein the channel length parameter of the first transistor and the channel length parameter of each third transistor are identical, but the channel width parameter for each third transistor may mutually differ.

In addition, the present invention further provides a method for frequency response switching, comprising the following steps: initially, providing an input impedance by disposing a source inductive degeneration amplification circuit; then, using N cascode circuits to connect in parallel to the source inductive degeneration amplification circuit, where N is a positive integer; finally, using N switches to respectively connect to each of the cascode circuits and enabling or disabling each switch to control the turned ON or OFF status in each cascode circuit, thereby switching a frequency response characteristic in the source inductive degeneration amplification circuit.

Herein the source inductive degeneration amplification circuit comprises a first transistor, a second transistor, a first inductor, a second inductor and a third inductor. The drain of the first transistor is connected to the source of the second transistor, the first inductor is connected between the gate of the first transistor and an input terminal, the second inductor is connected between the source of the first transistor and a ground, one terminal of the third inductor is connected to the drain of the second transistor and an output terminal, and the other terminal of the third inductor is connected to a first voltage source.

Herein each cascode circuit respectively comprises a third transistor and a fourth transistor. In each cascode circuit, the source of the fourth transistor is connected to the drain of the third transistor, the drain of the fourth transistor is connected to the drain of the second transistor, the gate of the fourth transistor is connected to the second resistor, and the source of the third transistor is connected to the source of the first transistor.

Herein each of the cascode circuits respectively comprises a third transistor, and in each of the cascode circuits, the source of the second transistor is connected to the drain of the third transistor, and the source of the third transistor is connected to the source of the first transistor.

Herein the channel length parameter of the first transistor and the channel length parameter of each third transistor are identical, but the channel width parameter for each third transistor may mutually differ.

In summary of the aforementioned descriptions, the low noise amplifier and the method for frequency response switching according to the present invention feature one or more of the following advantages:

(1) The low noise amplifier with variable frequency response and the method for frequency response switching according to the present invention allow controlling the ON or OFF status of the cascode circuit through enabling or disabling the switch, thereby altering the frequency response characteristic of the source inductive degeneration amplification circuit.

(2) The low noise amplifier with variable frequency response and the method for frequency response switching according to the present invention have the same overdrive voltage in order to effectively ensure impedance match on different frequency bands.

### BRIEF DESCRIPTION OF THE DRAWINGS

FIG. 1 is a circuit diagram for a cascode low noise amplifier in prior art;

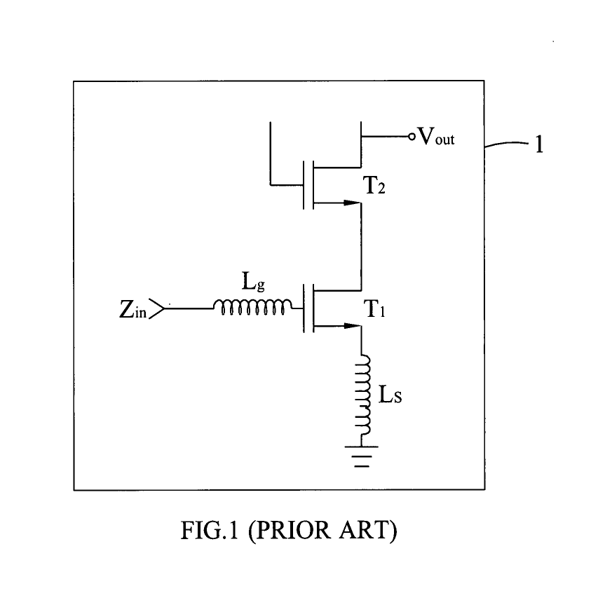

FIG. 2 is a block diagram for a first embodiment of the low noise amplifier with variable frequency response according to the present invention;

FIG. 3 is a block diagram for a second embodiment of the low noise amplifier with variable frequency response according to the present invention;

FIG. 4 is a block diagram for a third embodiment of the low noise amplifier with variable frequency response according to the present invention;

FIG. 5 is a diagram of frequency response for the reflection coefficient S11 and the transmission coefficient S21 in the second embodiment according to the present invention; and

FIG. 6 is a stepwise flowchart for implementation of the method for frequency response switching according to the present invention.

### DETAILED DESCRIPTION OF THE INVENTION

The low noise amplifier with variable frequency response according to the present invention essentially makes use of the conventional cascode low noise amplifier and, through the ON or OFF status in the multiple cascode circuits connected in parallel to the cascode low noise amplifier, modifies with equivalent effectiveness the channel width parameter of the primary transistor in the cascode low noise amplifier, thereby altering the frequency response characteristic of the low noise amplifier with variable frequency response according to the present invention. Therefore, certain features found in the conventional cascode low noise amplifier can be inherited, and the advantage of multi-band switching can be achieved by means of equivalently effective modification on the channel width parameter of the primary transistor.

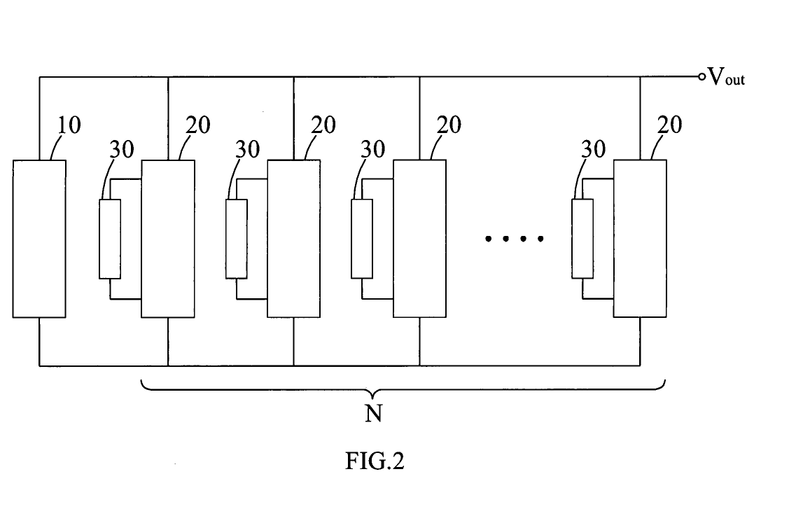

Refer to FIG. 2, wherein a block diagram for a first embodiment of the low noise amplifier with variable frequency response according to the present invention is shown. In the figure, the low noise amplifier 1 with variable frequency response comprises a source inductive degeneration amplification circuit 10, N cascode circuits 20 and N switches 30, where N is a positive integer. The source inductive degeneration amplification circuit 10 has an input impedance Zin and a frequency response characteristic. The N cascode circuits 20 are mutually connected in parallel, and one terminal of the parallel connection is coupled to the output terminal Vout of the source inductive degeneration amplification circuit 10, while the other terminal thereof is connected to the source of the source inductive degeneration amplification circuit 10. The N switches 30 are respectively connected to each corresponding cascode circuit 20 thereby allowing to set the ON or OFF status in the correspondingly connected cascode circuit 20 through enabling or disabling each switch 30, so as to change the channel width parameter of the transistor in the source inductive degeneration amplification circuit 10, thus accordingly altering the frequency response characteristic of the source inductive degeneration amplification circuit 10.

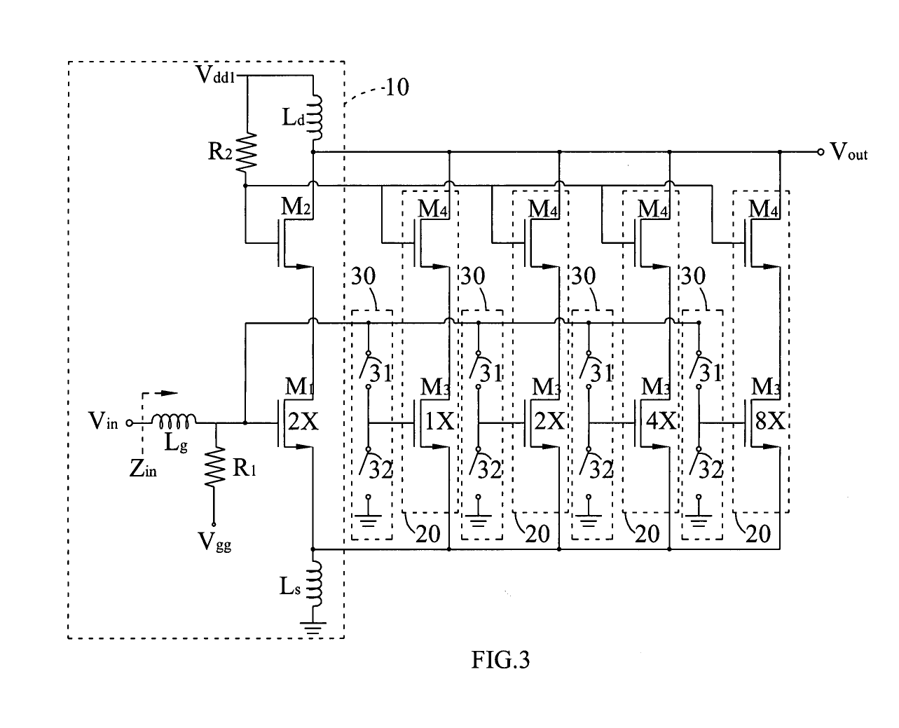

Refer next to FIG. 3, wherein a block diagram for a second embodiment of the low noise amplifier with variable frequency response according to the present invention is shown. In the figure, the low noise amplifier 1 with variable frequency response comprises a source inductive degeneration amplification circuit 10, four cascode circuits 20 and four switches 30, and the input impedance Zin of the source inductive degeneration amplification circuit 10 may be 50 Ohm (Ω) or 75 Ω.

The source inductive degeneration amplification circuit 10 comprises a first transistor M1, a second transistor M2, a first inductor Lg, a second inductor Ls, a third inductor Ld, a first resistor R1 and a second resistor R2. The drain of the first transistor M1 is connected to the source of the second transistor M2.

The first inductor Lg is connected between the gate of the first transistor M1 and an input terminal Vin; the second inductor Ls is connected between the source of the first transistor M1 and a ground; one terminal of the third inductor Ld is connected to the drain of the second transistor M2 and an output terminal Vout. The first inductor Lg and the second inductor Ls provide the required input impedance Zin; the other terminal of the third inductor Ld is connected to a first voltage source Vdd1, and the third inductor Ld can be used as a direct current RF choke.

The first resistor R1 is connected between the gate of the first transistor M1 and a second voltage source Vgg, such that the gate of each third transistor M3 has the same overdrive bias voltage as the gate of the first transistor M1; the second resistor R2 is connected between the gate of the second transistor M2 and the first voltage source Vdd1, such that the second transistor M2 has the same overdrive voltage value as each fourth transistor M4.

Each cascode circuit 20 comprises a third transistor M3 and a fourth transistor M4. In each of the cascode circuits 20, the source of the fourth transistor M4 is connected to the drain of the third transistor M3, the drain of the fourth transistor M4 is connected to the drain of the second transistor M2, the gate of the fourth transistor M4 is connected to the second resistor R2, and the source of the third transistor M3 is connected to the source of the first transistor M1. Herein the first transistor M1, the second transistor M2, each of the third transistors M3 and each of the fourth transistors M4 are N-typed semiconductor field effect transistors. In addition, the channel length parameter of the first transistor M1 is equal to the channel length parameter of each third transistor M3; whereas, the channel width parameter of each third transistor M3 is respectively ½, 1, 2 and 4 times as the channel width parameter of the first transistor M1. The multiplicities of the channel width parameter in each third transistor M3, the left-right arrangement positions for each third transistor M3 as well as the number of the cascode circuits illustrated in the present embodiment are simply exemplary, rather than being limited thereto.

Each of the switches 30 respectively comprises a first sub-switch 31 and a second sub-switch 32. In each switch 30, one terminal of the first sub-switch 31 is connected to the gate of the first transistor M1, the other terminal of the first sub-switch 31 is connected to the gate of the third transistor M3 and one terminal of the second sub-switch 32, while the other terminal of the second sub-switch 32 is connected to ground. When the first sub-switch 31 in the switch 30 is enabled, the second sub-switch 32 in the switch 30 is disabled, and contrarily, when the first sub-switch 31 in the switch 30 is disabled, the second sub-switch 32 in the switch 30 is enabled. The behavior of such a corresponding ON or OFF in the first sub-switch 31 and the second sub-switch 32 can be accomplished by means of an inverter; that is, so long as the first sub-switch 31 is connected to the input terminal of the inverter, and the second sub-switch 32 is connected to the output terminal thereof, it is possible to allow that the first sub-switch 31 and the second sub-switch 32 correspondingly demonstrate opposite switching condition.

When the first sub-switch 31 is ON, the second sub-switch 32 is OFF, thereby allowing the corresponding third transistor M3 and the first transistor M1 to have an identical overdrive voltage, such that the third transistor M3 becomes conductive, facilitating the connection in parallel between the first transistor M1 and the active third transistor M3, thus effectively equivalent to the enlargement in the channel width parameter of the first transistor M1, which, consequently, can be deemed as controlling the variation in channel width parameter of the first transistor M1 in accordance with the status in the switch 30. The more the number of the active third transistors M3 is, the greater the channel width parameter of the first transistor M1 becomes, thus enabling reduction in the matching frequency of the frequency response, so as to switch between different frequency response characteristics.

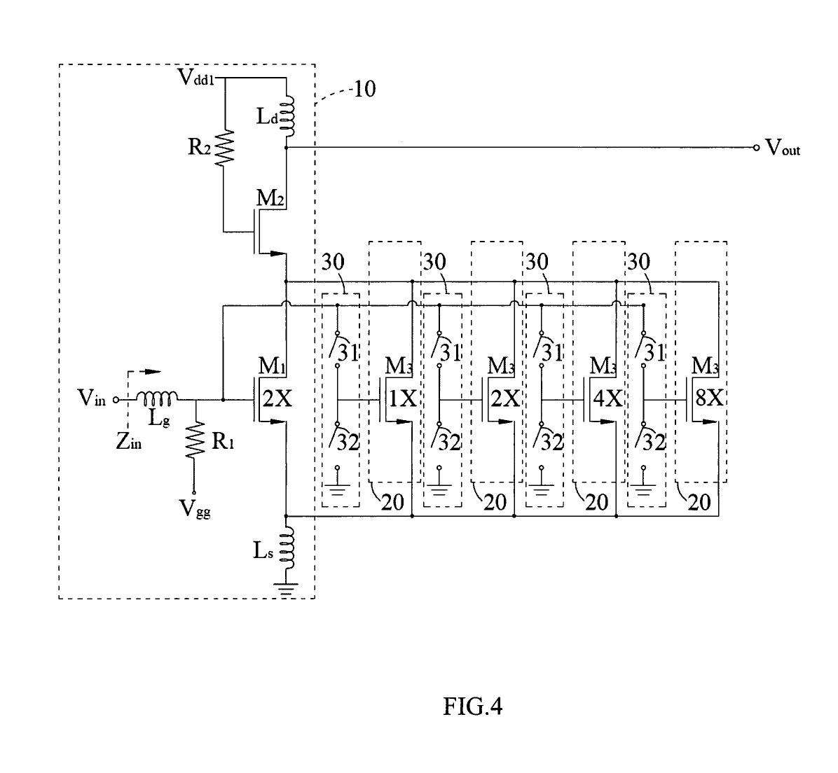

Refer next to FIG. 4, wherein a block diagram for the third embodiment of the low noise amplifier with variable frequency response according to the present invention is shown. In the figure, the low noise amplifier 1 with variable frequency response comprises a source inductive degeneration amplification circuit 10, four cascode circuits 20 and four switches 30, and the input impedance Zin of the source inductive degeneration amplification circuit 10 may be 50 Ohm (Ω) or 75 Ω.

The source inductive degeneration amplification circuit 10 comprises a first transistor M1, a second transistor M2, a first inductor Lg, a second inductor Ls, a third inductor Ld, a first resistor R1 and a second resistor R2. The drain of the first transistor M1 is connected to the source of the second transistor M2.

The first inductor Lg is connected between the gate of the first transistor M1 and an input terminal Vin; the second inductor Ls is connected between the source of the first transistor M1 and a ground; one terminal of the third inductor Ld is connected to the drain of the second transistor M2 and an output terminal Vout. The first inductor Lg and the second inductor Ls provide the required input impedance Zin; the other terminal of the third inductor Ld is connected to a first voltage source Vdd1, and the third inductor Ld can be used as a direct current RF choke.

The first resistor R1 is connected between the gate of the first transistor M1 and a second voltage source Vgg, such that the gate of each third transistor M3 has the same overdrive bias voltage as the gate of the first transistor M1; the second resistor R2 is connected between the gate of the second transistor M2 and the first voltage source Vdd1.

Each parallel circuit 20 comprises a third transistor M3. In each of the parallel circuits 20, the source of the third transistor M3 is connected to the source of the first transistor M1. Herein the first transistor M1, the second transistor M2, and each of the third transistors M3 are N-typed semiconductor field effect transistors. In addition, the channel length parameter of the first transistor M1 is equal to the channel length parameter of each third transistor M3; whereas, the channel width parameter of each third transistor M3 is respectively ½, 1, 2 and 4 times as the channel width parameter of the first transistor M1. The multiplicities of the channel width parameter in each third transistor M3, the left-right arrangement positions for each third transistor M3 as well as the number of the cascode circuits illustrated in the present embodiment are simply exemplary, rather than being limited thereto.

Each of the switches 30 respectively comprises a first sub-switch 31 and a second sub-switch 32. In each switch 30, one terminal of the first sub-switch 31 is connected to the gate of the first transistor M1, the other terminal of the first sub-switch 31 is connected to the gate of the third transistor M3 and one terminal of the second sub-switch 32, while the other terminal of the second sub-switch 32 is connected to ground. When the first sub-switch 31 in the switch 30 is enabled, the second sub-switch 32 in the switch 30 is disabled, and contrarily, when the first sub-switch 31 in the switch 30 is disabled, the second sub-switch 32 in the switch 30 is enabled. The behavior of such a corresponding ON or OFF in the first sub-switch 31 and the second sub-switch 32 can be accomplished by means of an inverter; that is, so long as the first sub-switch 31 is connected to the input terminal of the inverter, and the second sub-switch 32 is connected to the output terminal thereof, it is possible to allow that the first sub-switch 31 and the second sub-switch 32 correspondingly demonstrate opposite switching condition.

When the first sub-switch 31 is ON, the second sub-switch 32 is OFF, thereby allowing the corresponding third transistor M3 and the first transistor M1 to have an identical overdrive voltage, such that the third transistor M3 becomes conductive, facilitating the connection in parallel between the first transistor M1 and the active third transistor M3, thus effectively equivalent to the enlargement in the channel width parameter of the first transistor M1, which, consequently, can be deemed as controlling the variation in channel width parameter of the first transistor M1 in accordance with the status in the switch 30. The more the number of the active third transistors M3 is, the greater the channel width parameter of the first transistor M1 becomes, thus enabling reduction in the matching frequency of the frequency response, so as to switch between different frequency response characteristics.

In Table 1, as shown hereunder, the relationship between the status of each switch 30 and the frequency response characteristic, along with reflection coefficient S11, transmission coefficient S21, noise figure (NF), input third-order intercept point (IIP3) and power consumption, is illustrated. In the Switch Status column as illustrated, each of the 4 digits respectively indicates the turn ON or turn OFF status in individual one of the four third transistors M3 from left to right; e.g., “1001” represents the left most and right most third transistors M3 are turned ON circuits (conductive), while the two located in the middle are turned OFF circuits (broken). In this case of “1001”, the first transistor M1 is connected in parallel to two third transistors M3, and the channel width parameter for such two third transistors M3 are respectively 0.5 and 4 times of the first transistor M1, hence it is equivalently in effectiveness to modify the channel width parameter of the first transistor M1 from the original W to W//0.5 W//4 W. As a result, it is possible to switch the matching frequency of the frequency response from the original 5.4 GHz to 3.1 GHz.

TABLE 1

| | Matching | Reflection | Transmission | Noise | Input Third-Order | Power |
|---|---|---|---|---|---|---|
| Switch | Frequency | Coefficient | Coefficient | Figure | Intercept | Consumption |
| Status | (GHz) | (dB) | (dB) | (dB) | Point (dBm) | (mW) |
| 1111 | 2.5 | −21.3 | 16.91 | 2.16 | 0.50 | 24.3 |
| 1110 | 2.6 | −22.8 | 16.91 | 2.27 | 0.49 | 22.0 |
| 1101 | 2.7 | −24.3 | 16.90 | 2.31 | 0.42 | 21.3 |
| 1100 | 2.8 | −26.7 | 16.97 | 2.31 | −0.20 | 20.4 |
| 1011 | 2.9 | −27.5 | 16.88 | 2.32 | −0.21 | 18.5 |
| 1010 | 3.0 | −30.7 | 16.92 | 2.30 | −0.23 | 16.1 |
| 1001 | 3.1 | −30.4 | 16.89 | 2.40 | −0.45 | 15.5 |
| 1000 | 3.2 | −37.0 | 16.91 | 2.42 | −0.65 | 13.4 |
| 0111 | 3.3 | −33.9 | 16.87 | 2.45 | −0.75 | 12.4 |
| 0110 | 3.5 | −35.9 | 16.80 | 2.63 | −0.78 | 11.1 |
| 0101 | 3.7 | −30.4 | 16.74 | 2.74 | −1.10 | 9.9 |
| 0100 | 3.9 | −27.7 | 16.70 | 2.81 | −2.00 | 8.4 |
| 0011 | 4.2 | −25.6 | 16.20 | 2.77 | −2.46 | 7.1 |
| 0010 | 4.5 | −26.9 | 15.79 | 2.73 | −2.63 | 5.6 |
| 0001 | 4.9 | −32.4 | 15.37 | 2.67 | −3.20 | 4.2 |
| 0000 | 5.4 | −20.5 | 15.11 | 2.20 | −3.98 | 3.6 |

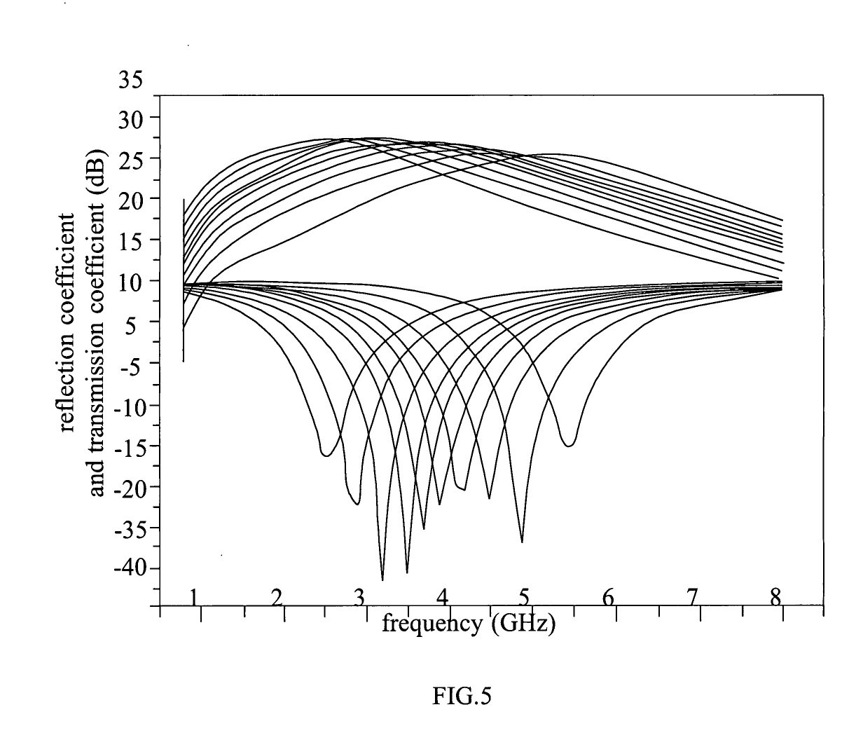

Refer now to FIG. 5, wherein a diagram of frequency response for the reflection coefficient S11 and the transmission coefficient S21 in the second embodiment according to the present invention is shown. In the Figure, the frequency response characteristics corresponding to S11 and S21 vary depending on the switching status in the four third transistors M3, thereby achieving the objective of switching among different frequency response characteristics according to the present invention.

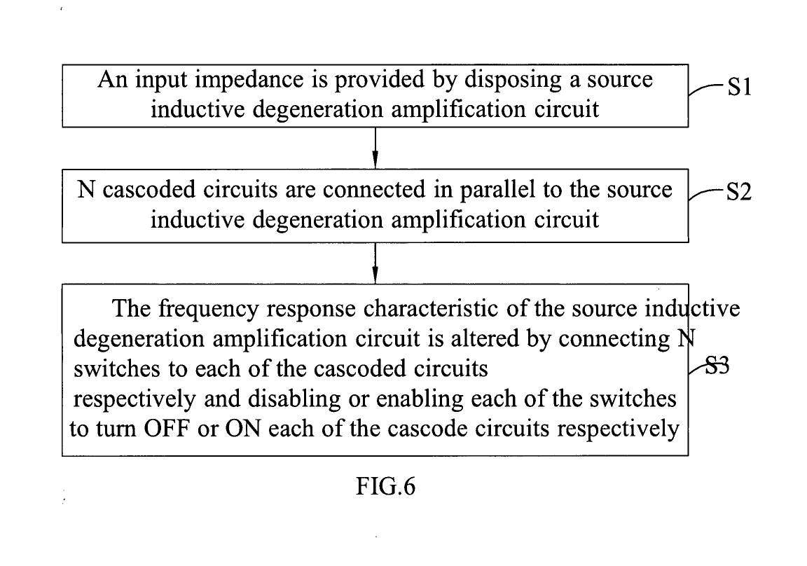

Refer finally to FIG. 6, wherein a stepwise flowchart for implementation of the method for frequency response switching according to the present invention is shown. In the Figure, the method for frequency response switching comprises the following steps:

in Step S1, an input impedance is provided by disposing a source inductive degeneration amplification circuit;

in Step S2, N cascode circuits are connected in parallel to the source inductive degeneration amplification circuit; and

in Step S3, the frequency response characteristic of the source inductive degeneration amplification circuit is altered by connecting N switches to each of the cascode circuits respectively and disabling or enabling each of the switches to turn OFF or ON each of the cascode circuits respectively.

What is claimed is:

1. A low noise amplifier with variable frequency response, comprising:
a source inductive degeneration amplification circuit with an input impedance and a frequency response characteristic, the source inductive degeneration amplification circuit comprising at least one output terminal and at least one inductor with one terminal connecting to a ground;
N cascode circuits, where N is a positive integer, each of the cascode circuits being connected in parallel between the output terminal of the source inductive degeneration amplification circuit and the other terminal of the inductor; and
N switches, each of the switches being respectively connected to each of the cascode circuits, the frequency response characteristic being altered by disabling or enabling each of the switches to turn ON or OFF each of the cascode circuits respectively.

2. The low noise amplifier with variable frequency response according to claim 1, wherein the source inductive degeneration amplification circuit comprises a first transistor, a second transistor, a first inductor, a second inductor and a third inductor, the drain of the first transistor is connected to the source of the second transistor, the first inductor is connected between the gate of the first transistor and an input terminal, the second inductor is connected between the source of the first transistor and the ground, one terminal of the third inductor is connected to the drain of the second transistor and an output terminal, and the other terminal of the third inductor is connected to a first voltage source.

3. The low noise amplifier with variable frequency response according to claim 2, wherein the source inductive degeneration amplification circuit further comprises a first resistor and a second resistor, the first resistor is connected between the gate of the first transistor and a second voltage source; the second resistor is connected between the gate of the second transistor and the first voltage source.

4. The low noise amplifier with variable frequency response according to claim 3, wherein each of the cascode circuits respectively comprises a third transistor and a fourth transistor, and in each of the cascode circuits, the source of the fourth transistor is connected to the drain of the third transistor, the drain of the fourth transistor is connected to the drain of the second transistor, the gate of the fourth transistor is connected to the second resistor, and the source of the third transistor is connected to the source of the first transistor.

5. The low noise amplifier with variable frequency response according to claim 4, wherein the first transistor, the second transistor, each of the third transistors and each of the fourth transistors are N-typed semiconductor field effect transistors.

6. The low noise amplifier with variable frequency response according to claim 5, wherein the channel length parameter of the first transistor is equal to the channel length parameter of each of the third transistors.

7. The low noise amplifier with variable frequency response according to claim 4, wherein the channel width parameter of each of the third transistors are different.

8. The low noise amplifier with variable frequency response according to claim 4, wherein the channel width parameters of each of the third transistors are the same.

9. The low noise amplifier with variable frequency response according to claim 4, wherein each of the switches respectively comprises a first sub-switch and a second sub-switch, one terminal of the first sub-switch is connected to the gate of the first transistor, the other terminal of the first sub-switch is connected to the gate of the third transistor and one terminal of the second sub-switch, while the other terminal of the second sub-switch is connected to ground, and when the first sub-switch in each of the switches is enabled, the second sub-switch in each switch is disabled, and when the first sub-switch in each switch is disabled, the second sub-switch in each switch is enabled.

10. The low noise amplifier with variable frequency response according to claim 3, wherein each of the cascode circuits respectively comprises a third transistor, and in each of the cascode circuits, the source of the second transistor is connected to the drain of the third transistor, and the source of the third transistor is connected to the source of the first transistor.

11. The low noise amplifier with variable frequency response according to claim 10, wherein the first transistor, the second transistor, and each of the third transistors are N-typed semiconductor field effect transistors.

12. The low noise amplifier with variable frequency response according to claim 11, wherein the channel length parameter of the first transistor is equal to the channel length parameter of each of the third transistors.

13. The low noise amplifier with variable frequency response according to claim 10, wherein the channel width parameter of each of the third transistors are different.

14. The low noise amplifier with variable frequency response according to claim 10, wherein the channel width parameters of each of the third transistors are the same.

15. The low noise amplifier with variable frequency response according to claim 10, wherein each of the switches respectively comprises a first sub-switch and a second sub-switch, one terminal of the first sub-switch is connected to the gate of the first transistor, the other terminal of the first sub-switch is connected to the gate of the third transistor and one terminal of the second sub-switch, while the other terminal of the second sub-switch is connected to ground, and when the first sub-switch in each of the switches is enabled, the second sub-switch in each switch is disabled, and when the first sub-switch in each switch is disabled, the second sub-switch in each switch is enabled.

16. The low noise amplifier with variable frequency response according to claim 1, wherein the input impedance is 50 Ohm (Ω) or 75 Ω.

17. A method for frequency response switching, comprising the following steps:
providing an input impedance by disposing a source inductive degeneration amplification circuit;
connecting N cascode circuits in parallel to the source inductive degeneration amplification circuit;
altering the frequency response characteristic of the source inductive degeneration amplification circuit by connecting N switches to each of the cascode circuits respectively and disabling or enabling each of the switches to turn ON or OFF each of the cascode circuits respectively.

18. The method for frequency response switching according to claim 17, wherein the source inductive degeneration amplification circuit comprises a first transistor, a second transistor, a first inductor, a second inductor and a third inductor, the drain of the first transistor is connected to the source of the second transistor, the first inductor is connected between the gate of the first transistor and an input terminal, the second inductor is connected between the source of the first transistor and a ground, one terminal of the third inductor is connected to the drain of the second transistor and an output terminal, and the other terminal of the third inductor is connected to a first voltage source.

19. The method for frequency response switching according to claim 18, wherein each cascode circuit is mutually connected in parallel between the source of the first transistor and the drain of the second transistor.

20. The method for frequency response switching according to claim 19, wherein the source inductive degeneration amplification circuit further comprises a first resistor and a second resistor, the first resistor is connected between the gate of the first transistor and a second voltage source; the second resistor is connected between the gate of the second transistor and the first voltage source.

21. The method for frequency response switching according to claim 20, wherein each cascode circuit respectively comprises a third transistor and a fourth transistor, and in each of the cascode circuits, the source of the fourth transistor is connected to the drain of the third transistor, the drain of the fourth transistor is connected to the drain of the second transistor, the gate of the fourth transistor is connected to the second resistor, and the source of the third transistor is connected to the source of the first transistor.

22. The method for frequency response switching according to claim 21, wherein the first transistor, the second transistor, each of the third transistors and each of the fourth transistors are N-typed semiconductor field effect transistors.

23. The method for frequency response switching according to claim 22, wherein the channel length parameter of the first transistor is equal to the channel length parameter of each of the third transistors.

24. The method for frequency response switching according to claim 21, wherein the channel width parameters of each of the third transistors are different.

25. The method for frequency response switching according to claim 21, wherein the channel width parameters of each of the third transistors are the same.

26. The method for frequency response switching according to claim 21, wherein each of the switches respectively comprises a first sub-switch and a second sub-switch, one terminal of the first sub-switch is connected to the gate of the first transistor, the other terminal of the first sub-switch is connected to the gate of the third transistor and one terminal of the second sub-switch, while the other terminal of the second sub-switch is connected to ground, and when the first sub-switch in each switch is enabled, the second sub-switch in each switch is disabled, and when the first sub-switch in each switch is disabled, the second sub-switch in each switch is enabled.

27. The method for frequency response switching according to claim 20, wherein each of the cascode circuits respectively comprises a third transistor, and in each of the cascode circuits, the source of the second transistor is connected to the drain of the third transistor, and the source of the third transistor is connected to the source of the first transistor.

28. The method for frequency response switching according to claim 27, wherein the first transistor, the second transistor, and each of the third transistors are N-typed semiconductor field effect transistors.

29. The method for frequency response switching according to claim 28, wherein the channel length parameter of the first transistor is equal to the channel length parameter of each of the third transistors.

30. The method for frequency response switching according to claim 27, wherein the channel width parameter of each of the third transistors are different.

31. The method for frequency response switching according to claim 27, wherein the channel width parameters of each of the third transistors are the same.

32. The method for frequency response switching according to claim 27, wherein each of the switches respectively comprises a first sub-switch and a second sub-switch, one terminal of the first sub-switch is connected to the gate of the first transistor, the other terminal of the first sub-switch is connected to the gate of the third transistor and one terminal of the second sub-switch, while the other terminal of the second sub-switch is connected to ground, and when the first sub-switch in each of the switches is enabled, the second sub-switch in each switch is disabled, and when the first sub-switch in each switch is disabled, the second sub-switch in each switch is enabled.

33. The method for frequency response switching according to claim 17, wherein the input impedance is 50 Ohm (Ω) or 75Ω.
